(19) United States
(12) Patent Application Publication
(10) Pub. No.: US 2019/0040520 A1
(43) Pub. Date: Feb. 7, 2019

(54) COATING FOR OPTICAL AND ELECTRONIC APPLICATIONS

(71) Applicant: ECOLE POLYTECHNIQUE FEDERALE DE LAUSANNE (EPFL), Lausanne (CH)

(72) Inventors: Anna KRAMMER, Lausanne (CH); Antonio PAONE, Lausanne (CH); Andreas SCHÜLER, Lausanne (CH)

(73) Assignee: ECOLE POLYTECHNIQUE FEDERALE DE LAUSANNE (EPFL), Lausanne (CH)

(21) Appl. No.: 16/074,674

(22) PCT Filed: Feb. 2, 2017
(86) PCT No.: PCT/IB2017/050557

§ 371 Date: Aug. 1, 2018

(30) Foreign Application Priority Data
Feb. 4, 2016 (IB) PCT/IB2016/050572

(51) Int. Cl. C23C 14/08; C23C 14/54; C23C 14/00; C23C 14/35; F24S 40/50; F24S 50/80; F24S 70/225; G02F 1/01

(52) U.S. Cl. CPC C23C 14/083; C23C 14/548; C23C 14/0042; C23C 14/35; G02F 2201/38; F24S 50/80; F24S 70/225; G02F 1/0147; F24S 40/50

(57) ABSTRACT

Single- or multilayered coating, such as a selective solar absorber coating or a coating being part of an integrated electronic circuit, comprising one or more layers containing germanium (Ge) doped VO₂₊ₓ, where −0.1≤x≤0.1.

### FIELD OF INVENTION

The invention relates to single- or multilayered coatings which may be advantageously used in selective solar absorbers or integrated electronic circuits.

### Definitions

In the present document, terms like thermochromism, absorptance, emittance and reflectance are widely used. For this reason, it seems necessary to summarize their meanings.

Thermochromism is a property of materials which undergo a reversible change in their optical properties, at a critical temperature.

Every heated object emits electromagnetic radiation. The wavelength and intensity of this spectrum is dependent on the temperature of the body and its characteristics. A black body is able to absorb entirely the incident radiation and to emit a spectrum which is dependent on the temperature of the body. Planck's law describes the spectral radiance B_{λ}^{b}(T) emitted by the surface of a black body in thermal equilibrium at a definite absolute temperature T:

$${B}_{λ}^{b} ( T ) = \frac{2 {hc}^{2}}{{λ}^{5}} \frac{1}{{e}^{( hc / λ {k}_{B} T )} - 1}$$

where λ represents the wavelength, k_{B} is the Boltzmann constant, h is the Planck constant, and c is the speed of light. λ is in μm and B_{λ}(T) in W·m⁻²·μm⁻¹.

The total power emitted (emissive power) per unit area at the surface of the black body is obtained by integrating B_{λ}^{b}(T) over its wavelength range. The Stephan-Boltzmann law gives the total energy radiated per unit surface area of a black body per unit time:

P=∫₀^{∞}B_{λ}^{b}(T)dλ=σT⁴

where σ is the Stefan-Boltzmann's constant.

In general, the electromagnetic radiation emitted and absorbed by a body (known as a grey body) is always less intense in comparison with that of the black body at the same temperature. The thermal emittance of a material εₜₕ is relative to the ability of its surface to emit energy in the form of electromagnetic radiation. It is the ratio between the energy radiated by a material and the energy radiated by a black body at the same temperature. The value of the thermal emittance can vary between 0 and 1. A black body has εₜₕ=1 while any real object has εₜₕ<1.

$${ɛ}_{th} = \frac{{\int }_{0}^{∞} {B}_{λ} ( T ) d λ}{{\int }_{0}^{∞} {B}_{λ}^{b} ( T ) d λ}$$

Metals are characterized by valence electrons in partially filled bands with extended wavefunctions that can contribute to electronic and thermal conduction. The corresponding Fermi energy, E_{F}, which describes the electron occupancy statistics, lies within the partially filled energy band. The resulting high density of free electrons is manifested in the characteristic high optical reflectance of most metals and corresponding low thermal emittance (εₜₕ<0.2). By contrast, the valence electrons of insulators are localized in a filled valence band (at 0K) that is separated by a quantum-mechanically forbidden band gap E_{g} from a largely unoccupied conduction band. In this case, the Fermi energy lies within the forbidden band gap. Photons with energies below E_{g} are transmitted by the insulator, while photons with energies above E_{g} are absorbed by the valence electrons, allowing electron transitions to the conduction band. Insulators are characterized by conductivities that increase exponentially with temperature and relatively high thermal emittances (εₜₕ>0.5).

The total hemispherical emittance εₕ refers to the emission in all the possible direction included in a hemisphere and for all the possible wavelengths.

$${ɛ}_{h} = \frac{{\int }_{0}^{∞} {\int }_{0}^{2 π} {\int }_{0}^{1} {ɛ}_{λ} ( μ , ϕ ) {B}_{b , λ} ( μ , ϕ ) μ d μ d ϕ d λ}{{\int }_{0}^{∞} {\int }_{0}^{2 π} {\int }_{0}^{1} {B}_{b , λ} ( μ , ϕ ) μ d μ d ϕ d λ}$$

Where

$${ɛ}_{λ} ( μ , ϕ ) = \frac{{B}_{λ} ( μ , ϕ )}{{B}_{λ}^{b} ( μ , ϕ )} .$$

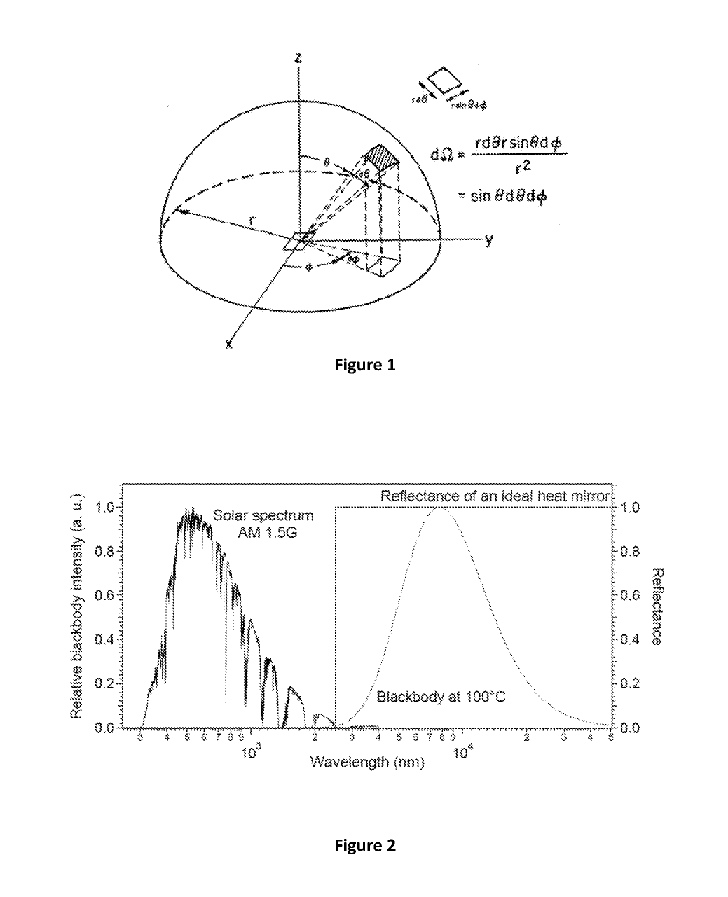

μ and φ indicate the incoming flux direction (direction is measured by the zenith and azimuthal angles θ and φ. μ=cos θ. See FIG. 1.)

The absorptance α of a plane surface is the fraction of incident radiation which is absorbed by the surface. If the surface is opaque to the radiation then absorptance and reflectance sum is unity. both specular absorptance α_{λ}(μ,φ) and specular reflectance ρ_{λ}(μ,φ) are functions of the wavelength of the radiation and the angle of incidence. There are many definitions of different kinds of absorptance, we cite only the definition useful for our considerations: the hemispherical absorptance.

$${α}_{h} = \frac{{\int }_{0}^{∞} {\int }_{0}^{2 π} {\int }_{0}^{1} {α}_{λ} ( μ , ϕ ) {B}_{λ , i} ( μ , ϕ ) μ d μ d ϕ d λ}{{\int }_{0}^{∞} {\int }_{0}^{2 π} {\int }_{0}^{1} {B}_{λ , i} ( μ , ϕ ) μ d μ d ϕ d λ}$$

Where

$${α}_{λ} ( μ , ϕ ) = \frac{{B}_{λ , a} ( μ , ϕ )}{{B}_{λ , i} ( μ , ϕ )} .$$

a, i are the abbreviations of absorbed and incident radiation and B_{λ}(μ,φ) represents the spectral irradiance of the radiation. The integrals are necessary to consider all the wavelengths and the incoming light from every direction of the hemispherical sphere.

In conclusion, we report Kirchhoff's law. It states that for a small body in an isothermal enclosure kept at constant temperature, in order to avoid violations of the second law of thermodynamics, the following equation is valid:

α_{λ}(μ,φ)=ϵ_{λ}(μ,φ)=1−ρ_{λ}(μ,φ)

where ρ_{λ}(μ,φ) represents the spectral reflectance relative to a specific wavelength and direction.

The solar absorptance is defined as the ability of a surface to absorb the solar radiation and is calculated as the ratio between the amount of absorbed and the incident solar energy. In this study the solar absorptance has been calculated over the solar spectrum from 0.366 μm to 2.5 μm. This interval covers the 95% of the whole AM 1.5 G solar spectrum. The temperature of the solar panel has been considered at 100° C.

An efficient selective surface is defined as having a high solar absorptance over the solar spectrum and, in addition, also having a low thermal emittance to reduce thermal radiative heat losses. In a thermal solar collector the substrate is usually an infrared mirror in order to stop these losses. The best combination would be to adopt a solar absorber which is optically thick (highly absorbing) in the solar range and optically thin (poorly absorbing, more transmitting) in the infrared range in such way that the substrate can play its role of providing low thermal emittance.

### STATE OF THE ART

A solar thermal panel or solar thermal collector is a device intended to collect heat from solar radiation. The main goal is to absorb sunlight energy as a blackbody, but without emitting thermal energy. The energy of sunlight is carried by electromagnetic radiation in the spectral range from the infrared to the ultraviolet. The collector has to convert the energy of the sun directly into a more usable or storable form and to behave as an infrared mirror in order to minimize thermal losses.

Solar thermal systems convert incoming solar radiation into heat and transfer the absorbed thermal energy to a heat transfer fluid (air, water or oil). The collected solar energy is then carried either to the hot water system or space heating system, or to a storage tank for later use. In addition to being efficient, solar thermal collectors must satisfy the requirements for architectural integration.

Solar water heating collectors are the most common solar thermal systems, proving very efficient in turning solar energy into thermal energy. They reach up to ˜85% efficiency in solar thermal conversion compared to direct conversion of solar electrical systems with only ˜17% efficiency. Due to these high efficiencies and ease of operation, solar water heating collectors play a major role in the residential building sector.

The central piece of a solar heating system is the solar collector, which absorbs the incoming solar radiation. Other components are the heat transfer fluid and the pipes, valves and pumps corresponding to the transfer circuit, the heat storage tank in order to store thermal energy for later use and, in some cases, alternative heat sources for cold periods with less sunshine. When the transfer fluid is water, it must be protected from overheating and freezing. Glycols might be added in order to avoid freezing during cold periods.

One key element of the thermal collector is the solar absorber, which has to maximize the absorption of solar radiation, while minimizing the thermal losses. The conversion efficiency of a collector system is limited by the thermal losses from the heated absorber due to conduction, convection and infrared radiation to the surroundings. The losses become increasingly significant at higher temperatures. As temperature increases, the losses increase and the conversion efficiency decreases. In order to be useful, the absorber should exhibit the property of optical selectivity. An efficient selective surface should exhibit a high solar absorptance over the solar spectrum (0.25-2.5 μm) and in addition a low thermal emittance to reduce thermal radiative heat losses. The achievement of such a surface with wavelength selective properties is possible due to the fact that the solar spectrum and the thermal infrared spectrum of heated bodies do not overlap to any appreciable extent (for temperatures below 500° C., 0.98 of the thermal infrared radiation occurs at wavelengths greater than 2 μm).

In FIG. 2., the standard solar spectrum at the surface of the Earth, AM 1.5 G and a normalized distribution of radiant energy for a blackbody at 100° C. are shown. The AM 1.5 G solar spectrum (G stands for global and includes both direct and diffuse radiation) is the relevant solar spectrum for mid-latitudes. Therefore, it is the most common because of many of the world's major population centers, solar installations and industry, across Europe, China, Japan, the United States of America and elsewhere (including northern India, southern Africa and Australia) lie in these latitudes. On the surface of the Earth during a clear day, at noon, the irradiance of direct solar energy is approximately 1000 W/m² for many of these locations.

The reflectance of an ideal selective surface is also depicted in FIG. 2. Reflectance should be zero over the solar spectrum and 1 over the 2.5 μm threshold. Without a selective coating, a thermal solar panel would emit the radiative energy of a blackbody at around 70° C.

Usually a competitive thermal solar collector should exhibit a solar absorptance αₛₒₗ≥0.95 and a thermal emittance εₜₕ≤0.05. In addition, the collector lifetime should amount to at least 25 years to be attractive in the market.

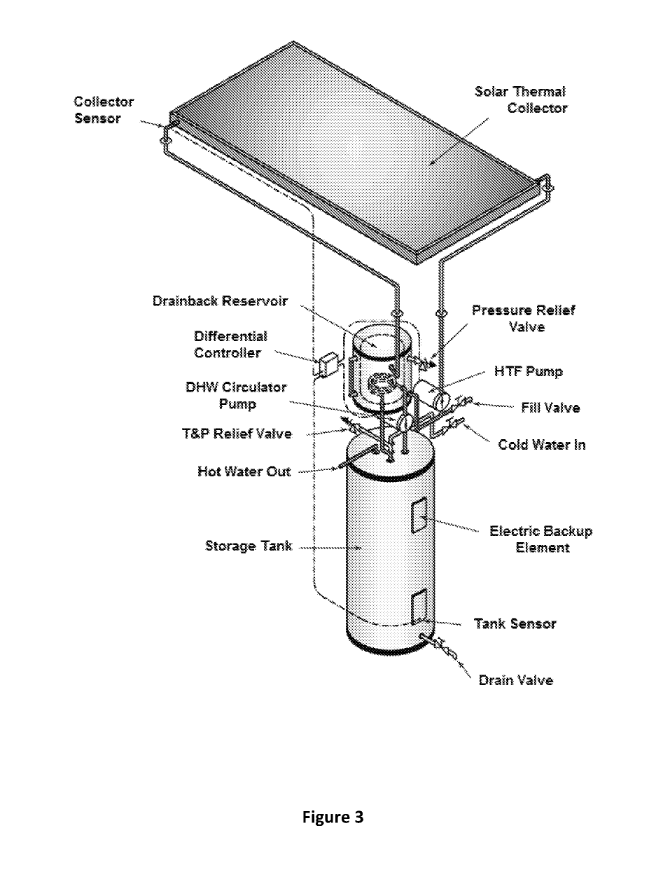

In a drainback thermal solar system (see FIG. 3.) the circulation of the liquid in the collector is shut off every time that the temperature of the liquid is out of a certain temperature range. The limits of this range are the freezing and the evaporation temperature of the liquid. The stagnation temperature is defined as the temperature of a solar system under no flow conditions. Practically, the stagnation temperature is reached under thermal equilibrium between the absorbed solar energy and the thermal losses during no flow conditions.

Unfortunately, solar collectors suffer from the problem of overheating during summer. The resulting stagnation temperature can reach 200° C. even in central European latitudes. Such high temperatures lead to water evaporation, glycol degradation, and mechanical stresses in the collector with increasing vapor pressure during stagnation. Additionally, the elevated temperatures lead to degradation of the materials that compose the collector, such as sealing, thermal insulation and the selective absorber coating. Special precautions are necessary to release this pressure; only mechanical solutions exist nowadays which complicate the construction and increase the system costs.

A promising way to avoid overheating of solar thermal systems without any mechanical device (e.g., for shading or for pressure release) is to provide a protection for solar thermal systems by thin film technology. A “smart” switchable solar absorber was envisioned. The performance and lifetime of the thermal solar collector would be increased by self-cooling of said collector upon reaching a critical temperature.

Limiting the stagnation temperature of solar collectors to a value below the boiling point of the heat transfer liquid, without degrading the optical performance of the selective coating, would produce the following advantages:
evaporation of the heat transfer liquid due to overheating would be avoided in such a way that the hydraulic system could be simplified;
the lifetime of the collector materials used for thermal insulation, the joints and the selective coating itself would increase;
the glycol component of the heat transfer liquid would be protected from degradation.

The optimal solution is to deposit a coating that increases its thermal emittance at a precise temperature and even decreases its absorptance at the same temperature. Thus, a coating with a poor optical selectivity above T_{C} would be desired. The change of properties should happen quickly and reversibly.

For this purpose, inorganic thermochromic selective coatings were considered, since it has been shown that the durability of organic thermochromic paints is not high enough for the considered solar thermal application. Inorganic durable material like VO₂ is a promising thermochromic material which exhibits a change in optical properties at a critical temperature T_{C}.

Vanadium dioxide VO₂ displays significant changes in physical properties when heated beyond 67-68° C. This material behaves like a semiconductor at lower temperatures, allowing more transmission, and like a conductor at higher temperatures, providing greater reflectance and less transmission in the infrared range. However, although the changes in the optical properties of VO₂ with temperature are quite striking for infrared wavelengths, the material does not exhibit such a pronounced contrast in the visible range. This means that IR radiation can be transmitted through this layer and be absorbed up to a critical temperature above which the IR radiation would be reflected in order to prevent overheating. A thermochromic coating on a metallic substrate would yield a surface characterized by a low thermal emissivity in the cold state and high thermal emissivity in the hot state, thus allowing the collector to get rid of the excess energy during overheating by radiating it. It could be quite attractive then to take advantage of these properties and use such tunable thermochromic layers to protect solar collectors from overheating.

However, for solar thermal collectors a suitable switching temperature of the thermochromic layer would be in the range of 80° C. and 100° C. Doping with different elements have been reported that can alter the thermochromic switching temperature of pure VO₂. High valence ions such as W⁶⁺, Mo⁶⁺, Nb⁵⁺, Ta⁵⁺, Ti⁴⁺, Ru⁴⁺ which behave as donors in VO₂ and have larger ionic radii than V⁴⁺, are believed to lower the transition temperature^{[2,3]}. Higher the valence of the cation, lower the transition temperature. Doping with low valence metal ions, such as Al³⁺, Ga³⁺, Cr³⁺ and Fe³⁺ which behave as acceptors and have small ionic radii, are thought to increase the transition temperature^{[3,4]}. Up to date, it is not clear whether the size or valence of the ion is the responsible factor for the change in transition temperature.

Morin discovered the metal-to-insulator transition in VO₂ in 1959^{[5]} and it sparked considerable interest. By the end of 70 s the effect of a wide variety of dopants were studied. These studies concerned mainly doped single crystals or powders and not thin films. However, in the extensive research that followed, studies have almost exclusively targeted dopants which could lower the transition temperature so that vanadium dioxide could be used in smart windows and in other applications with ambient temperature switching.

The majority of publications on dopants which could increase the T_{C} of vanandium dioxide are dating back to the 1960s and were limited to doped single crystals or powders. Studies on doped VO₂ thin films with increased transition temperature are scarce and, in some cases contradictory to the results obtained for single crystals and powders. In thin films, crystallite size, film stresses, film growth, presence of impurities etc. have a major influence on the behavior of thin films which could significantly differ from that in a single crystal or powders for the same material. When working with films, there are some controversial results, especially concerning Al³⁺ doping. Some papers report an increase^{[6,7]}, whereas others have shown a decreaser^{[8,9]} in the transition temperature while doping with Al³⁺. Different thin film deposition methods might be accountable for the contradictory results.

Studies carried out in the Solar Energy and Building Physics Laboratory (LESO-PB) of the École Polytechnique Fédérale de Lausanne, on thin films deposited by reactive magnetron sputtering have shown that Al³⁺ induces an amorphization of the films^{[1]}, thus losing the switching behavior. Cr³⁺ doping was unsuccessful too in raising the temperature. Cr³⁺ failed to enter the thin film structure and seemingly segregated forming chromium oxide islands in the films.

There are very few publications^{[10-12]} where Ge has been showed to have an effect on increasing the transition temperature of VO₂. However, this effect was reported only for single crystals and powders. To the best of the inventors' knowledge, studies on the effect of Ge doping in VO₂ thin films have not yet been published.

Furthermore, it must be noted that, due to the very complex phase diagram of the V-O system, it is uncommon and rather challenging to deposit pure VO₂ films. More often, the deposted vanadium oxide films contain phase mixtures of several VOₓ phases.

In 2008, a report for the Swiss Federal Office of Energy (SFOE), by authors Paone and Schüler, have been published on the “Evaluation of the Potential of Optical Switching Materials for Overheating Protection of Thermal Solar Collectors”^{[13]}. This is the earliest document suggesting the idea of achieving active cooling of collectors without any mechanical device for pressure release or collector emptying, by producing a selective coating which is able to switch its optical properties at a critical temperature T_{c}. This optical switch would allow changing the selective coating efficiency, the goal being to obtain a coating with a poor selectivity above T_{c} (decreasing of absorptance, increasing of emittance). In this purpose, the use of an inorganic thermochromic coating which switches from a semiconducting to a metallic state at critical temperature around 65° C. and undergoes a resistivity change of typically three orders of magnitude is reported.

Computer simulations of emittance have been carried out at the LESO-PB lab. It was shown that one of the thermochromic compounds becomes highly emissive in metallic state. So the thermal emittance is depending on the substrate at low temperature and then on the metallic state of the thermochromic compound after switching; the optimum layer thickness has been identified. First calculations led to projected emittance switching values from 5% in the cold state to ˜40% in the hot state. This means that a protection of glycol, sealing, selective coating, and insulating materials can be achieved by using this kind of layer in a selective coating (T kept under 160° C.).

In order to predict the overall performance of the coating, a selective multilayer containing thermochromic materials has been simulated. The most important finding is that emittance switching can be obtained without any degradation of the high optical selectivity in the cold state. It was shown that a solar absorptance of up to 97.3% can be obtained for a selective coating switching from 5% to approximately 35% in thermal emittance.

The document reported that stable high quality layers have been obtained using three different methods: sol-gel dip-coating, DC magnetron sputtering, and thermal evaporation. To obtain single-phased thermochromic samples a very good control of process settings is required.

From 2009 to 2014, yearly SFOE reports^{[14]} have been published by authors Paone and Schüler, documenting on the advances of their study of thermochromic based switchable selective absorber coatings for overheating protection of solar thermal collectors. The main objective of the SFOE project was to limit the stagnation temperature of solar collectors to a value below the boiling point of the heat transfer liquid without degrading the optical performance of the selective coating during normal operation.

In 2009, the study by Paone and Schüler concerned the determination of deposition processes for obtaining advanced thermochromic transition metal oxide films by vacuum evaporation and optimization of related processes. A control strategy for deposition of switchable films regarding Pₜₒₜ or O₂ flux was proposed. Structural and optical characterization of thermochromic films and determination of optical constants by spectroscopic ellipsometry were carried out.

In the 2010 SFOE report by A. Paone and A. Schüler, computer simulations for determining optimized multilayer designs for switching coatings were proposed. Based on the optical properties n & k of the thin film materials, the optical behaviour of individual layers and multilayered coatings are calculated. The computations are based on the method of the characteristic matrices for the film interference stacks and allow to predict and optimize the solar absorptance of the considered systems. In order to achieve a solar absorptance of 95% under operating conditions (typical requirement for solar thermal collectors), multilayers of different materials have to be designed by computer simulation, and fabricated by suitable thin film deposition processes.

For the first time, an optimized multilayered thermochromic coating with switching thermal emissivity and a solar absorptance of 96% below the transition temperature has been prepared. The multilayer was prepared by a combination of vacuum evaporation and sol-gel dip-coating.

Progress has also been made concerning the understanding of the switching mechanism. RBS and WDS analyses showed that already a tungsten doping of only 0.17 at % is sufficient to lower the transition temperature from 68° C. for pure VO₂ to 45° C. From literature, for a transition temperature of 45° C., a tungsten content of 1 at. % was expected. This result means that tungsten doping of the obtained VO₂ films is more effective than previously observed. Instead of segregating into an eventual second tungsten-rich phase, most of the tungsten atoms occupy sites in the crystal lattice, where they contribute to lowering the transition temperature.

In the 2011 SFOE report by Paone and Schüler, alternative metal alloy multilayers were identified. A life cycle analysis was carried out. The ecological impact of the production of solar thermal collectors is an important issue for a sustainable oriented market. The Life Cycle Analysis revealed that if the waste liquids are correctly treated and workers are not exposed to toxic substances, such as hexavalent chrome Cr(VI), the impact of the selective thin film is relatively small compared to that of a complete solar thermal system including heat storage, pumps, etc. The substrate material is an important factor in the evaluation of the environmental impact of a solar thermal collector. A copper substrate has a stronger impact than a substrate made from aluminium or stainless steel. Adding the function of overheating protection with a thermochromic coating does not change the impact significantly. The production of the thermochromic coatings can be considered as definitely less hazardous than the production of the conventional black chrome coating. Furthermore, preliminary experiments seemed to indicate that the transition temperature is not raised by Al doping.

In the 2012 SFOE report by Paone and Schüler, the feasibility of combining ε-switching coatings in a multilayer was studied. An optimized multilayer was simulated, which showed that the function of overheating protection using a thermochromic coating can be combined with optical selectivity. The absorptance of optimized multilayer deposited on aluminium substrate and containing a thermochromic film was also investigated for temperatures below and above the transition temperature. It has been proven that the thermochromic optical switching and optical selectivity are compatible and can be combined. Experiments seemed to indicate that the transition temperature is not raised by Al-doping of thermochromic films. Suitable strategies for raising the transition temperature with other dopants were proposed.

In 2013 and 2014 SFOE reports published by Paone and Schüler, the energy losses due to the mismatch of the transition temperature (for the pure thermochromic material, the transition temperature of 68° C. is relatively low and should be increased) were estimated, by computer simulations, to be below 14%. Although, literature studies suggested that it might be possible to increase the transition temperature by doping the coatings with aluminium, experiments showed that aluminium doping has led to an amorphization of the film structure, leaving the transition temperature unchanged. Using a novel type of doping, it was shown that it is principally possible to increase the transition temperature. In preliminary experiments, a transition temperature of 85° C. has been achieved. Possible approaches for further optimisation might be a variation of the process parameters such as the substrate temperature, or doping by other elements.

The switch in thermal emissivity limits the temperature of the absorber to values below the temperature of degradation of glycol (160° C.−170° C.). However, it would be preferable to limit the temperature in order to avoid the formation of water-glycol mixture as well.

In 2009, a paper entitled “Thermochromic films of VO₂:W for “smart” solar energy applications” is published by Paone et al.^{[15]}, where thermal evaporation by resistance heating is used to deposit VO₂:W films on glass slides and silicon wafer. By XRD analysis, the presence of one single monoclinic VO₂:W phase has been confirmed. By W-doping, the transition temperature can be lowered to approximately 45° C. The spectrophotometric measurements indicate a maximal transmittance switch for VO₂:W films on glass from 53% in the semiconducting state to around 1% in the metallic state at a wavelength of 2100 nm. The maximal reflectance switches in a complementary way, from 14% to 71% at a wavelength around 2000 nm. Between the two states, the emissivity of VO₂:W on glass jumps from 85% to 34%. This corresponds to an emissivity change by a factor of 2.5.

The optical constants n and k were investigated by ellipsometry in the visible and near infrared. The reproducibility and the accuracy of the ellipsometric measurements have been verified. The optical constants of VO₂:W show a high temperature-dependence in the near infrared range. At 2300 nm, k changes by a factor of 5.3 between the cold state and the hot state. At 1265 nm, the value of n is reduced by a factor of 0.4.

The optical simulation based on the determined n and k values yields results which are rather close to the spectrophotometric data.

In his thesis from 2013, entitled “Switchable Selective Absorber Coatings for Overheating Protection of Solar Thermal Collectors”^{[1]}, Paone discusses the issue of overheating in solar collectors and proposes a “smart” thermochromic coating as solution for such problems. He studies vanadium dioxide, as a durable inorganic thermochromic material for this purpose. Furthermore, he studies the effect of doping on altering the critical temperature of the VO₂ thin films obtained by co-sputtering. In order to simulate the optical behavior of multilayered solar coatings, precise knowledge of the optical properties of the material is required. In his study the complex dielectric functions of VO₂ and VO₂:W were determined by spectroscopic UV-VIS-NIR-MIR ellipsometry above and below the transition temperature. The optical constants of VO₂ show a considerable change in the near/middle infrared range. The maximum k (extinction coeffcient) change of a factor 7.4 between the semiconducting state and the metallic state occurs at 13490 nm. Reflectance and absorptance were measured by spectrophotometry in the near infrared range up to 20 μm in order to be compared with the computer simulations based on the determined optical properties of the material. A solar absorptance of 0.96 below the transition temperature was reported for a VO₂ based absorber. The thermal emittance of new nanocomposite materials based on VO₂ was also investigated applying the Bruggeman effective medium approximation. A thermal emittance switch from 0.08 to 0.32 was simulated for a 350 nm thick VO₂:W film mixed with a 40% volume fraction of SiO₂. The glycols used in solar thermal collectors start to degrade above 170° C. The use of this coating as solar absorber lowers the stagnation temperature below this critical point. In his thesis, the characterization of the optical properties of VO₂ and VO₂:W is reported. This characterization shows that these coatings are efficient absorbers for thermochromic solar thermal panels.

Based on some published studies stating that Al doping should increase the transition temperature of VO₂, Paone et al. attempt Al doping in order to alter the T_{C} of pure VO₂ thin films. However, Al³⁺ induces an amorphization of the films obtained by means of magnetron co-sputtering. In his work, he does not report on having successfully found a dopant which could increase the transition temperature of a pure VO₂ thin film.

In 2014, Paone et al. published on “Thermal solar collector with VO₂ absorber coating and V₁₋ₓWₓO₂ thermochromic glazing—Temperature matching and triggering” in Solar Energy. In this work, the authors propose a new way of protecting solar thermal systems from overheating without any mechanical device, indicating a new approach for dynamic thermal solar collectors. A switch of the thermal emittance can be achieved by a VO₂ absorber coating, and by doping the material with tungsten, it is possible to lower the transition temperature making it suitable as a glazing coating. The possibility of using the switch in emittance of the absorber coating in order to trigger the transition of a thermochromic coating on the glazing of the solar collector has been investigated. The investigations showed that in its current form this combination of a VO₂ solar absorber and of a V₁₋ₓWₓO₂ coating on the glazing of the solar collector is not yet satisfying and would have to be improved for the envisaged application.

Patent application WO2012069718^{[17]} discloses the use of a material layer with changing surface morphology in function of temperature in order to limit the absorptance of the material at high temperatures. The absorptance of a material is increasing with the roughness of its surface. Therefore, the proposed material has a surface morphology with a high roughness below a critical temperature, exhibiting a relatively high absorptance coefficient. Above the critical temperature, the morphology of the film changes and exhibits a less rough surface than in the low temperature form. The specular reflectance increases and the material absorbs less efficiently the electromagnetic radiation. The use of such a material in a solar panel is claimed to limit the stagnation temperature below 180° C. This document also proposes the option of combining a surface changing material with an absorbant layer based on a thermochromic material where the transmittance in the far infrared is relatively high, below a critical temperature T_{C}, and significantly lower above the T_{C}. WO2012069718 proposes VO₂, V₂O₅ or a doped vanadium oxide, without mentioning the nature of the dopant, as thermochromic material for the absorber layer. In practice, the deposition of layers with changing surface morphology at industrial scale is rather complex. On the other hand, using a VO₂ layer alone, although allows for the reduction in the stagnation temperature, it is not sufficient to avoid the degradation of the transfer fluid and can not allow for the use of cheaper materials in the construction of the solar panel's frame neither.

A more efficient, thermochromic based absorbant material for solar thermal collectors is disclosed in the patent application WO2014/140499 Al^{[18]}. It proposes a multilayered material including: a substrate having a reflectance greater than 80% for radiation within the far infrared range, a selective layer including a combination of VO₂ and VₙO₂ₙ₊ᵢ, where the selective layer exhibits a solar absorptance greater than 75% for radiation having a wavelength of 0.4 to 2.5 μm regradless of temperature and, for the 6 to 10 μm range, having a variable transmittance in function of T_{C} such as, at T<T_{C} the transmittance Tr>85%, while for T>T_{C} transmittance is 20%≤Tr≤50%. It is mentioned that the material can be doped with metals like Al, Cr or Ti or with metallic oxides as M₁₋ₓOₓ.

The document proposes different combinations for the selective layer such as:
a mix of VO₂ and V₄O₉, or
a mix of VO₂ and V₆O₁₃, or
a mix of VO₂, V₄O₉ and Al₂O₃.

This prior art mentions that the Al doped selective layer exhibits a critical temperature between 80 and 120° C. This statement does not correspond with the experimental results obtained by the inventors of the present patent application, where Al doping induced amorphization of vanadium dioxide thin films, without influencing their transition temperature. The behavior of thin films is dependent on many parameters, complicated thin film chemistry, stresses and other thin film effects might be responsible for the contradictory results.

Our main proposed application clearly targets selective absorber coatings for next generation smart solar collectors. However, vanadium dioxide films have raised overwhelming interest in a variety of applications. VO₂ is currently considered as one of the most promising materials for oxide electronics. Its ultrafast, sub-picosecond transition, marked by abrupt changes in electrical properties (˜4 orders of magnitude resistivity drop), established VO₂ as a prominent candidate for electrical switches^{[19]}, tunable capacitors^{[20]}, memristors^{[21]} etc.

These recent developments at microelectronic device level emphasize the importance of a precise control of the transition temperature, in a wide range, above the critical temperature of pure VO₂ (68° C.). For a successful integration of VO₂ into electronic circuits and prevention of premature switching of vanadium dioxide components due to the operation at elevated temperatures, high-temperature switching VO₂ is required.

General Description of the Invention

The present invention is based on the surprising observation of increased switching temperature in a single or multilayered coating which includes at least one Ge doped VO₂₊ₓ containing layer (−0.1≤x≤0.1), where x designates slight stoichiometric deviations from the perfect VO₂ phase.

The present invention more precisely concerns a multilayered material including one or more thermochromic layers containing Ge doped VO₂₊ₓ (˜0.1≤x≤0.1). This material may be advantageously used as the key component of a switchable selective solar absorber, that can successfully protect solar thermal collectors from overheating during stagnation.

The germanium doped VO₂₊ₓ (˜0.1≤x≤0.1) based switchable solar absorber decreases the stagnation temperature of solar collectors by changing its optical properties, primarily in the region of infrared wavelengths. Limiting the stagnation temperature the degradation of collector materials is avoided, the construction of the solar thermal systems simplified, the costs reduced and lifetime of the device extended. This is achieved by self-cooling of the device upon reaching the critical temperature of the thermochromic germanium doped VO₂₊ₓ (˜0.1≤x≤0.1) containing layer. Such a thermochromic coating on a metallic substrate yields a surface characterized by a low thermal emissivity in the cold state, below T_{C}, and high thermal emissivity in the hot state, above T_{C}, thus allowing the collector to get rid of the excess energy during overheating by radiating it.

The particular advantage of Ge doping is that it surprisingly and successfully increases the transition temperature of VO₂₊ₓ (−0.1≤x≤0.1) thin films into the desired range, and to the best of our knowledge, it does so for the first time in thin films. This effect has been long seeked by the inventors and took considerable effort to identify. Experiments on doping of VO₂ are especially time-consuming: due to the multitude of existing phases in the binary vanadium-oxygen system, the process window for producing the exact stoichiometry of VO₂ is very narrow, and small modifications of the process, such as adding a mechanism for doping, make the process parameters easily drift out of the allowed range.

The majority of existing literature on doped VO₂ addresses the issue of decreasing the transition temperature for its use in smart windows or other room temperature applications. Studies concerning dopants which could potentially increase the transition temperature are scarce and contradictory when it comes to thin films. Low valence ions with small ionic radii such as Al³⁺, Ga³⁺, Cr³⁺ etc have been traditionally thought to increase the transition temperature of vanadium dioxide, however results in thin films emerged as being controversial. Al³⁺ doping has been reported as both increasing^{[6,7]} and decreasing^{[8,9]} the transition temperature. The inventors of the present application have been carried out some experiments on aluminium and chromium doped vanadium dioxide thin films and both were found to be unsuccessful in raising the critical temperature. Al³⁺ doping induces amorphization of VO₂ thin films, while Cr³⁺ fails to enter the structure of the thin film and appears to segregate. Thus, it has been shown that using dopants which are thought to increase the transition temperature is not evident as their effect in thin films is unpredictable.

The effect of Ge doping has been even less documented than for the other elements and it was referred to solely in the context of powders and single crystals. It was, therefore, surprising to discover its effect on vanadium dioxide thin films, considering also previous experiences with Al and Cr doping.

In addition to germanium raising the transition temperature, the resistivity values of the high temperature VO₂₊ₓ (˜0.1≤x≤0.1) phase are increasing, thus lowering its metallic character, making it from so called “bad” metal—with relatively high resistivity—to “worse” with even higher resistivity. As its reflectance decreases, absorptance increases, hence its thermal emittance increases as well, making it a better heat radiator above the critical temperature. A more efficient heat dissipation leads to a faster self-cooling of the device.

Last but not least, a very important advantage of Ge doping is the reducing and, depending on doping level, even disappearance of the hysteresis width exhibited by pure VO₂. Then, the collector does not need to be undercooled to switch back into the low emitting, semiconducting state, but reduces its thermal emittance as soon as the collector cools down to or near the critical temperature inferred upon heating.

The reasons why germanium is producing the above mentioned effects is not fully understood, mainly because of the lack of thorough understanding of the underlying physics of the involved strongly correlated electron system.

However, for Ge to induce these changes in the VO₂₊ₓ (˜0.1≤x≤0.1) based thin films, deposition conditions and parameters must be carefully controlled. The working pressure in the chamber, the oxygen partial pressure must be kept between well defined limits. Small fluctuations in oxygen partial pressure may lead to other vanadium oxides than VO₂, which do not exhibit a thermochromic transition around 68° C. Nonetheless, the presence of small amounts of other vanadium oxides, besides VO₂₊ₓ (˜0.1≤x≤0.1), can exhibit beneficial effects in raising the thermal emissivity of the coating.

It should also be underlined that contrary to the previous cited prior art, the coating according to the invention does not imply the use of any surface morphology changing material, while still allowing for important reduction in stagnation temperature.

### DETAILED DESCRIPTION OF THE INVENTION

The invention will be better understood in the present chapter, in association with the following figures (some of them being already presented in the previous chapters):

FIG. 1: The characterization of radiance usually is made in solid angles. Direction is measured by the zenith and azimuthal angles θ and φ. μ=cos θ. This is an example of a hemisphere^{[1]}

FIG. 2: Solar spectrum at AM 1.5 G, the normalized emission spectrum of a blackbody at 100° C. and the reflectance curve of an ideal solar absorber^{[1]}

FIG. 3: A complete drainback thermal solar system. Credits: Home Power Inc.

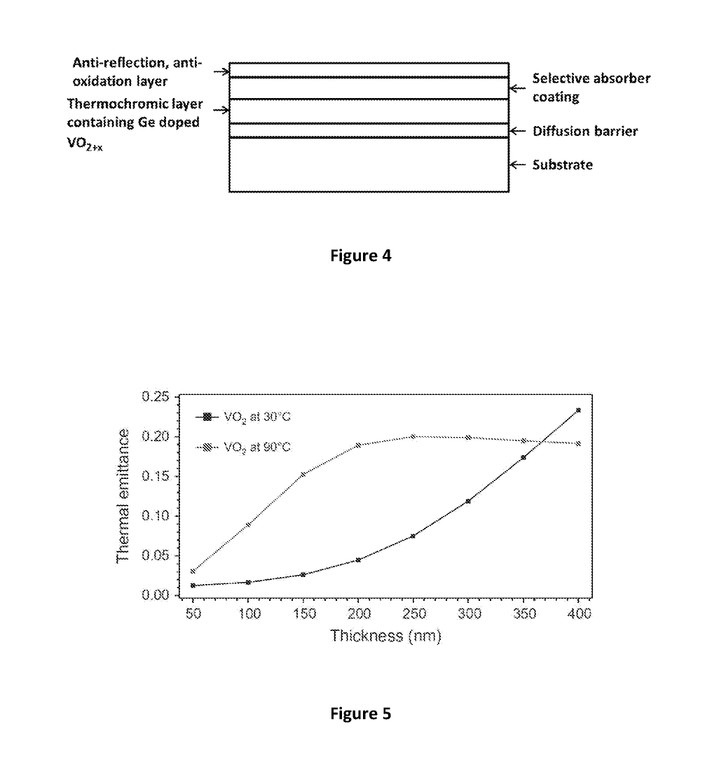

FIG. 4: Schematic of a possible layer stack for a switchable selective absorber coating

FIG. 5: Simulation of the thermal emittance switch with increasing thickness for pure VO₂^{[16]}

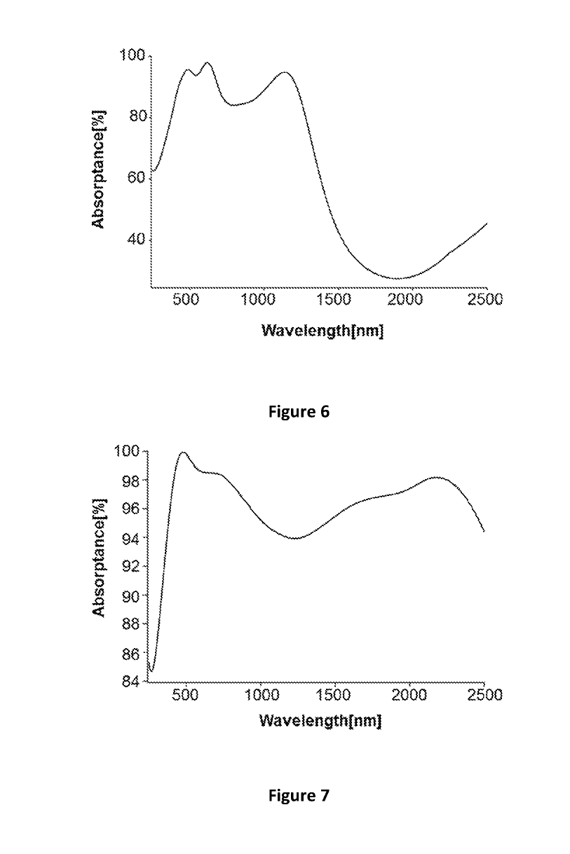

FIG. 6: Spectral absorptance of a design containing: 250 nm VO₂ and 80 nm SiO₂ on Al below T_{C}

FIG. 7: Spectral absorptance of a multilayer design containing: 250 nm VO_{2/180} nm a-C:H/Ti 37%/100 nm a-C:H/Ti 11%/70 nm a-C:H/Ti 0.12%/80 nm SiO₂ on Al

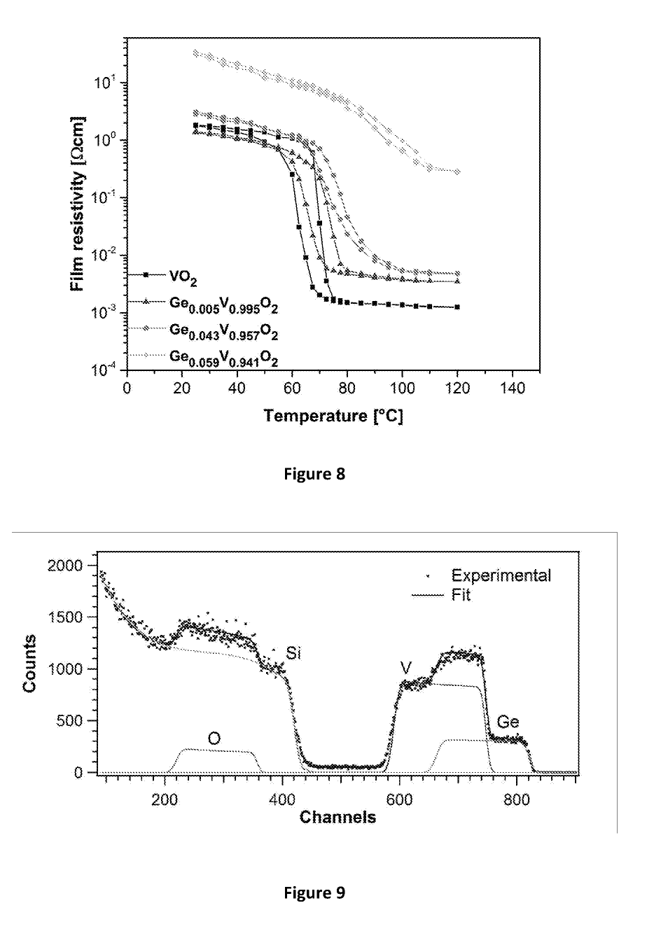

FIG. 8: Resistivity measurements of Ge doped samples. Effect of doping on the transition temperature

FIG. 9: Experimental data (points) and simulated RBS spectra (solid line) of such a Ge doped VO₂₊ₓ (˜0.1≤x≤0.1) based film on Si (100) substrate. The result of the simulation agrees well with the experimental RBS spectrum and the Ge concentration was determined to be 5.9 at. %.

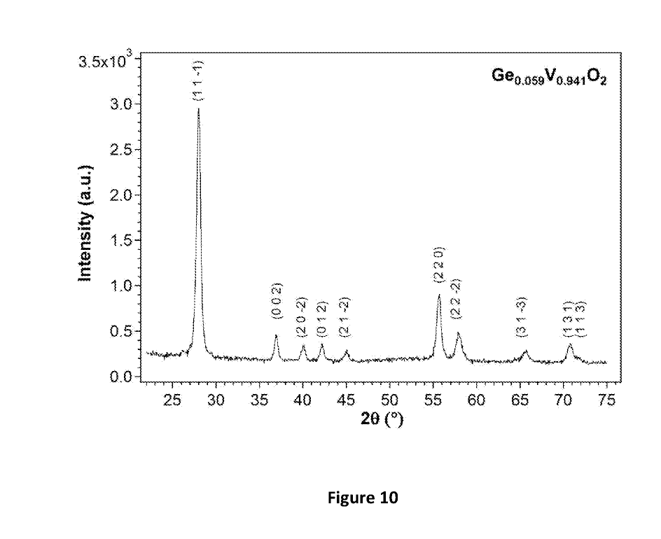

FIG. 10: XRD spectra of a Ge doped VO₂₊ₓ (˜0.1≤x≤0.1) based film on Si (100) substrate. All diffraction lines were assigned to the stoichiometric VO₂ monoclinic phase according to [Rakotoniaina, J. C. et al., J. Solid State Chem. 103, 81-94 (1993)].

The single- or multilayerd material according to the invention may be associated with the following features, the list being not exhaustive.
a highly infrared reflective substrate such as Al, Cu, stainless steel or any other mechanically stable substrate covered with a highly reflective thin film.
a diffusion barrier coating which would prevent the diffusion of elements from the substrate into the thermochromic film and could improve the adherence of said film onto the substrate. The diffusion barrier could be an AlOₓ, SiOₓ, metal nitrides or ternary compounds such as TiSiₓN_{y}, CrSiₓN_{y} etc. The thickness of the diffusion barrier is preferably between 20 and 90 nm.
a thermochromic layer containing Ge doped VO₂₊ₓ (˜0.1≤x≤0.1).
a selective absorber coating such as TiAlₓO_{y}N_{z}, TiSiₓO_{y}N_{z}, CrAlₓO_{y}N_{z}, CrSiₓO_{y}N_{z}, a-C:H/Me, a-Si:C:H/Me, TiAlₓN_{y}, NbTiₓO_{y}N_{z}/SiOₓN_{y} etc., where x, y, z≥0.
a top coating serving as both an anti-reflection layer and as oxidation barrier with a preferred thickness between 20 and 150 nm. e.g.: SiOₓ, AlOₓ etc.

One variant of stacking the layers is shown in FIG. 4. Other multilayered structures, containing all or several of the above mentioned layers, are possible and can be imagined.

The key element is the Ge doped VO₂₊ₓ (˜0.1≤x≤0.1) containing layer which may be obtained by a very strictly controlled reactive magnetron co-sputtering process. The substrate temperature during the deposition is a critical parameter in order to obtain highly crystalline thin films. Amorphous films do not exhibit optical switching, therefore a high enough temperature is required. It was determined that, depending on the substrate holder used in the process, a temperature between 400° C. and 650° C. is necessary to obtain crystalline and, therefore, switching doped VO₂₊ₓ (˜0.1≤x≤0.1) films.

Furthermore, it is preferred that the doping is kept between certain limits as a strong doping leads to the loss of the switching character of the film. The preferred range of the Ge atomic concentration is between 0.01 at % and 7 at %. Ge increases the insulating character of the films and at higher concentrations of Ge than the one set as the upper limit of doping, the switching of the doped film from semiconducting to metallic state is lost.

The deposted thermochromic layer can then contain a mixture of one or more dopant elements, one of which is Ge, one or more metal oxides coming from said doping elements (e.g. GeOₓ) and at least VO₂₊ₓ (˜0.1≤x≤0.1), however not exclusively, as small or large amounts of other vanadium oxides can be present.

Computer simulation has been carried out and the thermal emittance was calculated using Planck's law. The thickness of a VO₂ based film is critical with regard to the thermal emittance switch. FIG. 5 clearly shows that the VO₂ based film becomes more and more emissive in the semiconducting state by increasing the film thickness. For thin VO₂ based films, at low temperature the thermal emittance is prevalently due to the substrate and at T>Tₜ to the VO₂ based film. The thickness of the thermochromic layer is suggested to preferably be between 70 and 330 nm.

The thickness of the thermochromic layer is critical regarding the selective coating efficiency. A 5 to 25% thermal emittance switch of the thermochromic selective coating has been simulated in order to get the efficiency of the whole system. A solar absorptance of about 85% is obtained by using an antireflective SiO₂ layer on VO₂ (see FIG. 6). This coating already behaves as an efficient selective surface.

FIG. 7. shows that a solar absorptance efficiency up to 97.3% is obtained for the full solar spectrum using a selective stack of five layers. The solar absorptance below T_{C} is not affected by the thermochromic layer of optimum thickness (needed for emittance switch).

The results are therefore promising for VO₂ based thermochromic layers. However, in a solar thermal system high temperatures occur and the switching of pure VO₂ at 68° C. is not sufficient. A solar thermal system with a thermochromic layer switching at higher than 68° C. critical temperatures leads to higher quantities of absorbed energy, therefore, higher efficiencies. For solar thermal collectors a suitable switching temperature of the thermochromic layer is in the range of 80° C. and 100° C.

The base pressure in the deposition chamber is in the range of 3·10⁻⁸ mbar. The temperature is between 400° C. and 650° C., depending on the sample holder. Ar is used as process gas. The O₂ partial pressure is precisely controlled with the help of a PID feedback control which keeps the O₂ partial pressure constant in the chamber by regulating the oxygen valve. During co-sputtering, the presence of a second plasma coming from the doping element introduces perturbations in the deposition chamber. The oxygen flow has to be adjusted in function of target depletion. An eroded target is sputtered more efficiently as the magnets are closer to its surface and the magnetic field is more intense. Therefore, the oxygen content has to be adjusted in function of how used the target is. The optimal deposition parameters for doped VO₂₊ₓ (˜0.1≤x≤0.1) based thermochromic films were inferred. The process parameters were kept in the following ranges:

Target substrate distance: 2-15 cm,

Rotation speed of the substrate: 1-50 rot/min,

Speed of substrate displacement: 0.05-4 m/min,

Process pressure: 5·10⁻⁴ mbar to 5·10⁻² mbar,

Oxygen partial pressure: 5·10⁻⁵ mbar to 5·10⁻³ mbar.

The deposition can be done using pure or composite or alloy targets containing germanium and/or vanadium during the co-sputtering process.

The RBS (Rutherford Backscattering Spectrometry) and X-ray diffraction spectra of a such deposited Ge doped VO₂₊ₓ (˜0.1≤x≤0.1) based thin film is shown in FIGS. 9 and 10 respectively.

As already mentioned the single- or multilayered material according to the invention is primarily intended for solar thermal applications. It may however be used in other applications such as solid state storage applications, reconfigurable microelectronics, steep-slope devices, RF switches, capacitors with variable capacitance, PV technology or chip technology. For these applications, high-temperature switching VO₂ films are required and highly seeked.

### BIBLIOGRAPHY

[1] Paone A., Switchable Selective Absorber Coatings for Overheating Protection of Solar Thermal Collectors, PhD Thesis No 5878, EPFL, 2013
[2] Burkhardt W. et al. W- and F-doped VO2 films studied by photoelectron spectrometry. Thin Solid Films 345, 229-235 (1999).
[3] Macchesney J. B., Guggenheim H. J. Growth and Electrical Properties of Vanadium Dioxide Single Crystals Containing J Phys. Chem. Solids 30, 225-234 (1969).
[4] Béteille F., Livage J. Optical Switching in VO2 Thin Films. J. Sol-Gel Sci. Technol. 921, 915-921 (1998).
[5] Morin F. J. Oxides which show a metal-to-insulator transition at the Neel temperature. Phys. Rev. Lett. 3, 34-36 (1959).
[6] Lu S., Hou L., Gan F. Surface analysis and phase transition of gel-derived VO₂ thin films. Thin Solid Films 353, 40-44 (1999).
[7] Wu Y. et al. A novel route to realize controllable phases in an aluminum (Al3+)-doped VO2 system and the metal-insulator transition modulation. Materials Letters 127, 44-47 (2014).
[8] Chen B., Yang D., Charpentier P. A., Zeman M. Al3+-doped vanadium dioxide thin films deposited by PLD. Solar Energy Materials and Solar Cells 93, 1550-1554 (2009).
[9] Gentle A., Smith G. B. Dual metal-insulator and insulator-insulator switching in nanoscale and Al doped VO2. J. Phys. D: Appl. Phys. 41, 015402 (2008).
[10] Futaki H. et al. Thermistor composition containing vanadium dioxide, U.S. Pat. No. 3,402,131, (1965)
[11] Futaki H., Aoki M. Effects of Various Doping Elements on the Transition Temperature of Vanadium Oxide Semiconductors, Jpn. J. Appl. Phys. 8 1008-1013 (1969)
[12] Kitahiro I., Watanabe A. Shift of Transition Temperature of Vanadium Dioxide Crystals, Jpn. J. Appl. Phys. 6 1023 (1967)
[13] Huot G., Roecker C., Schüler A., Evaluation of the Potential of Optical Switching Materials for Overheating Protection of Thermal Solar Collectors, SFOE project #102016 (2008).
[14] Paone A., Schüler A. Advanced switchable selective absorber coatings for overheating protection of solar thermal collectors, SFOE project #102016 (2009-2014).
[15] Paone A., Joly M., Sanjines R., Romanyuk A., Scartezzini J.-L., Schüler A. Thermochromic films of VO₂:W for “smart” solar energy applications, Proc. SPIE 7410, 74100F (2009)
[16] Paone A., Geiger M., Sanjines R., Schüler A. Thermal solar collector with VO₂ absorber coating and V₁₋ₓWₓO₂ thermochromic glazing Temperature matching and triggering, Solar Energy 110, 151-159 (2014).
[17] Viessmann Faulquemont, Absorbent material and solar panel using such material, Patent WO2012/069718 A1, (2012)
[18] Viessmann Faulquemont, Absorbent material and solar panel using such material, Patent WO2014/140499 A1, (2014)
[19] Vitale W. A., Moldovan C. F., Paone A., Schüler A., Ionescu A. M., Fabrication of CMOS-compatible abrupt electronic switches based on vanadium dioxide. Microelectronic Engineering, vol. 145, p. 117-119 (2015).
[20] Vitale W. A. et al. Tunable Capacitors and Microwave Filters Based on Vanadium Dioxide Metal-Insulator Transition. 18th International Conference on Solid-State Sensors, Actuators and Microsystems Transducers 2015, Anchorage, Ak., USA (2015).
[21] Driscoll T. et al. Phase-transition driven memristive system. Applied Physics Letters, vol. 95, 043503 (2009).

1. Single- or multilayered coating, such as a selective solar absorber coating or a coating being part of an integrated electronic circuit, comprising at least one layer containing VO₂₊ₓ, with −0.1≤x≤0.1, doped with one or several elements and wherein one of those elements is germanium (Ge).

2. Coating according to claim 1 for use as a solar absorber wherein the temperature of the thermochromic transition in the said layer is above 75° C.

3. Coating according to claim 1 where the total cumulated layer thickness of the Ge doped VO₂₊ₓ (−0.1≤x≤0.1) containing layer is in the range from 70 nm to 330 nm.

4. Coating according to claim 1 with an atomic concentration of germanium in the VO₂₊ₓ (−0.1≤x≤0.1) containing layer in the range from 0.01 at. % and 7 at. %.

5. Coating according to claim 1 where a highly infrared reflective substrate such as Al, Cu, stainless steel is used.

6. Coating according to claim 1 comprising a diffusion that contains AlOₓ, SiOₓ, metal nitrides or ternary compounds such as TiSiₓN_{y}, CrSiₓN_{y} etc. . . . and wherein the thickness of said barrier is between 20 and 90 nm.

7. Coating according to claim 1 where one or more layers of solar absorbing layers are used, such as e.g. TiAlₓO_{y}N_{z}, TiSiₓO_{y}N_{z}, CrAlₓO_{y}N_{z}, CrSiₓO_{y}N_{z}, a-C:H/Me, a-Si:C:H/Me, TiAlₓN_{y}, NbTiXO_{y}N_{z}, SiOₓN_{y}, where x, y, z≥0.

8. Coating according to claim 1 where a top coating is used as anti-reflection layer with a thickness between 20 and 150 nm and wherein the real part of the refractive index of this top coating is in the range from 1.4 to 1.8 at a wavelength of 550 nm.

9. Coating according to claim 8 where the top coating contains SiOₓ or AlOₓ.

10. Coating according to claim 1 where the layer containing Ge doped VO₂₊ₓ (−0.1≤x≤0.1) is deposited by reactive magnetron sputtering using a pure target, a composite target, an alloy target or several targets containing vanadium or germanium.

11. Coating according to claim 10 where the power density on the sputtering target is between 2 W/cm² and 50 W/cm² for a target containing vanadium and/or germanium.

12. Coating according to claim 10 where the power density on the sputtering target is between 0.05 W/cm² and 10 W/cm² for the germanium containing target used in cosputtering.

13. Coating according to claim 1 where the layer containing Ge doped VO₂₊ₓ (−0.1≤x≤0.1) is deposited with a substrate temperature in the range from 400° C. to 650° C.

14. Coating according to claim 1 where the layer containing Ge doped VO₂₊ₓ (−0.1≤x≤0.1) is deposited with stationary substrate, rotating substrate at a speed in the range from 1 to 50 rotations/min, or translational displacement with a speed in the range of 0.05 m/min and 4 m/min.

15. Coating according to claim 1 where the layer containing Ge doped VO₂₊, (−0.1≤x≤0.1) is deposited at a total pressure in the range from 5·10⁻⁴ mbar to 5·10⁻² mbar.

16. Coating according to claim 1 where the layer containing Ge doped VO₂₊ₓ (−0.1≤x≤0.1) is deposited at an oxygen partial pressure in the range from 5·10⁻⁵ mbar to 5·10⁻³ mbar.

17. Coating according to claim 1 where the target substrate distance is in the range from 2 cm to 15 cm.

18. Thermal solar collector containing a coating according to claim 1, said coating being used as selective solar absorber.

19. Thermal solar collector according to claim 18 comprising a thermochromic or thermotropic glazing.

20. Thermal solar energy system containing a solar collector according to claim 18.

21. Electronic circuit containing a coating according to claim 1.
